(19) United States
(12) Patent Application Publication
(10) Pub. No.: US 2005/0241571 A1
(43) Pub. Date: Nov. 3, 2005

(54) Method of growing nitride single crystal on silicon substrate, nitride semiconductor light emitting device using the same, method of manufacturing the same

(75) Inventors: Min Ho Kim, Suwon (KR); Masayoshi Koike, Suwon (KR); Hun Joo Hahm, Sungnam (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: Samsung Electro-Mechanics Co., Ltd., Suwon (KR)

(21) Appl. No.: 11/007,206

(22) Filed: Dec. 9, 2004

(30) Foreign Application Priority Data
Apr. 28, 2004 (KR) 2004-29477

(51) Int. Cl. C30B 25/00

(52) U.S. Cl. 117/89

(57) ABSTRACT

A method of growing a nitride single crystal layer, and a method of manufacturing a light emitting device using the method are disclosed. The method of growing a nitride single crystal layer comprises the steps of preparing a silicon substrate having an upper surface of a crystal plane (111), forming a buffer layer having the formula of SiₓGe₁₋ₓ, (where 0<x≦1) on the upper surface of the silicon substrate, and forming a nitride single crystal on the buffer layer. Also, a nitride light emitting device using the method manufactured by the method, and a method of manufacturing the same are disclosed.

### RELATED APPLICATION

The present invention is based on, and claims priority from, Korean Application No. 2004-29477, filed on Apr. 28, 2004, the disclosure of which is incorporated by reference herein in its entirety.

### BACKGROUND OF THE INVENTION

1. Field of the Invention

The present invention relates to a method of growing a nitride single crystal, and, more particularly, to a method of growing a high quality nitride single crystal on a silicon substrate, a nitride semiconductor light emitting device using the same, and a method of manufacturing the nitride semiconductor light emitting device.

2. Description of the Related Art

A nitride semiconductor light emitting device is a high power optic device, which generates light having a short wavelength, such as blue or green light, and thereby enables full color to be realized, and is spotlighted in the field of related technologies. Generally, a nitride semiconductor light emitting device is made of a nitride single crystal having the formula AlₓIn_{y}Ga_{(1-x-y)}N (where 0≦x≦1, 0≦y≦1, 0≦x+y≦1).

In order to manufacture such a nitride semiconductor light emitting device, it is necessary to provide a technology for growing a high quality nitride single crystal. However, there is a problem in that substrates currently used for growing the nitride single crystal are not appropriate due to differences in lattice parameters and thermal expansion coefficients between the substrate and the nitride single crystal.

Generally, the nitride single crystal is grown on a dissimilar substrate, such as a sapphire (Al₂O₃) substrate or a SiC substrate, by means of the MBE (Molecular Beam Epitaxy) process or a vapor phase growth process, such as the MOCVD (Metal Organic Chemical Vapor Deposition) process, the HVPE (Hydride Vapor Phase Epitaxy) process, etc.

Since the dissimilar substrate, such as a sapphire (α-Al₂O₃) substrate or a SiC substrate, is not only high priced, but also very restricted to a size of 2 or 3 inches, it is not appropriate for mass production.

Accordingly, it is needed to use a Si substrate, which is most generally used as a substrate in the semiconductor industry, including the light emitting device industry. However, due to differences in lattice parameter and thermal expansion coefficient between the Si substrate and a GaN single crystal, there is a problem in that cracks can be created at an interface between the sapphire substrate and the GaN single crystal to such an extent that the GaN layer cannot be practically used. As for a method of relieving the differences, provision of a buffer layer on the Si substrate has been suggested, but this method is not regarded as an appropriate method for solving the problem as mentioned above. FIGS. 1a and 1b show a GaN single crystal grown by use of a conventional AlN buffer layer and a buffer structure, which is combined with the AlN buffer layer and an AlGaN intermediate layer.

First, as shown in FIG. 1a, a conventional AlN buffer layer 12 is formed on a (111) plane of a Si substrate 11, and a GaN single crystal 15 having a thickness of 2 μm is grown on the AlN buffer layer 12. FIG. 2a is an optical micrograph showing a surface of the GaN single crystal 15 of FIG. 1a. As shown in FIG. 2a, it can be seen that a plurality of cracks are created on the surface of the GaN single crystal 15. These cracks are created due to unresolved differences in lattice parameter and thermal expansion coefficient between the Si substrate and the GaN single crystal, thereby not only deteriorating performance of the device and life span thereof, but also making it impossible to use the GaN single crystal in practice.

As an alternative method, as shown in FIG. 1b, with an AlN buffer layer 12 formed on a (111) plane of a Si substrate 11, a AlₓGa₁₋ₓN intermediate layer 13 having Al compositions (x) of 0.87 to 0.07 and a total thickness of 300 nm is formed on the AlN buffer layer 12, and a GaN single crystal 15 having a thickness of 2 μm is grown thereon. FIG. 2b is an optical micrograph showing a surface of the GaN single crystal 15 of FIG. 1b. As shown in FIG. 2b, it can be seen that, although the number of cracks created on the surface of the GaN single crystal 15 of FIG. 1b is decreased in comparison to the GaN single crystal 15 of FIG. 2a, a number of cracks are still created on the surface of the crystal 15 of FIG. 1b. That is, it can be understood that the buffer structure suggested in FIG. 1b cannot satisfy requirements for growing the high quality single crystal.

Accordingly, in the field of the prior art, there is a need to provide a method of growing a high quality nitride single crystal layer, which does not create cracks, on an Si substrate, and a nitride semiconductor light emitting device using the same.

### SUMMARY OF THE INVENTION

The present invention has been made to solve the above problems, and it is an object of the present invention to provide a method of growing a nitride single crystal layer, using a buffer layer comprising Si and Ge in order to allow a high quality nitride single crystal layer to be grown on a silicon substrate.

It is another object of the present invention to provide a nitride semiconductor light emitting device comprising a nitride single crystal layer grown on a silicon substrate, and a method of manufacturing the same.

In accordance with one aspect of the present invention, the above and other objects can be accomplished by the provision of a method of growing a nitride single crystal layer, comprising the steps of: preparing a silicon substrate having an upper surface of a (111) crystal plane; forming a buffer layer having the formula of SiₓGe₁₋ₓ, (where 0<x≦1) on the upper surface of the silicon substrate; and forming a nitride single crystal on the buffer layer.

The method may further comprise forming an intermediate layer having the formula of Al_{y}In_{z}Ga_{(1-y-z)}N, (where 0≦y≦1, 0≦z≦1, 0≦y+z≦1) on the buffer layer before forming the nitride single crystal.

The buffer layer may have an Si composition (x) of about 0.1˜0.2, and more preferably of about 0.14.

In order to efficiently reduce differences in lattice parameter and thermal expansion coefficient between the silicon substrate and the nitride single crystal, preferably, the buffer layer has an Si composition gradient (x) gradually decreasing from a portion, where the buffer layer contacts the silicon substrate, to an uppermost portion of the buffer layer. More preferably, the buffer layer has an Si composition gradient (x) gradually decreasing from 1 to 0.1 from the portion, where the buffer layer contacts the silicon substrate, to the uppermost portion of the buffer layer, respectively. Most preferably, the buffer layer has an Si composition gradient (x) gradually decreasing from 1 to 0.14 from the portion, where the buffer layer contacts the silicon substrate, to the uppermost portion of the buffer layer, respectively.

The buffer layer may have a thickness of at least 20 nm in order to sufficiently secure a buffering function.

In accordance with another aspect of the present invention, there is provided a nitride semiconductor light emitting device using the method of growing a nitride single crystal layer, the nitride semiconductor light emitting device comprising: a silicon substrate having an upper surface of a (111) crystal plane; a buffer layer having the formula of SiₓGe₁₋ₓ, (where 0<x≦1) on the silicon substrate; a first conductive nitride semiconductor layer on the buffer layer; an active layer on the first conductive nitride semiconductor layer; and a second conductive nitride semiconductor layer on the first conductive nitride semiconductor layer.

In accordance with yet another aspect of the present invention, there is provided a method of manufacturing a nitride semiconductor light emitting device by use of the method of growing a nitride single crystal layer, the method comprising the steps of: preparing a silicon substrate having an upper surface of a (111) crystal plane; forming a buffer layer having the formula of SiₓGe₁₋ₓ, (where 0<x≦1) on the silicon substrate; forming a first conductive nitride semiconductor layer on the buffer layer; forming an active layer on the first conductive nitride semiconductor layer; and forming a second conductive nitride semiconductor layer on the first conductive nitride semiconductor layer.

According to the present invention, the buffer layer employed for growing the nitride single crystal on the silicon substrate comprises a SiₓGe₁₋ₓ, layer, (where 0<x≦1). Since Si and Ge are perfectly soluble in the SiₓGe₁₋ₓ layer, there is an advantage in that the compositions of Si or Ge can be continuously varied from 0 to 1.

Additionally, in case of the conventional AlN buffer layer, there are differences of 24.8% and 40.7% in thermal expansion coefficient between the GaN layer and the AlN layer and between the AlN layer and the Si substrate, respectively, causing a severe problem of cracks due to the differences in thermal expansion coefficient. However, according to the present invention, since the Si_{0.14}Ge_{0.86} buffer layer has a thermal expansion coefficient approximately the same as that of the GaN layer, the problems caused by the differences in thermal expansion coefficient can be effectively solved.

### BRIEF DESCRIPTION OF THE DRAWINGS

The foregoing and other objects and features of the present invention will be more clearly understood from the following detailed description taken in conjunction with the accompanying drawings, in which:

FIGS. 1a and 1b show structures of a nitride single crystal grown on a silicon substrate according to a conventional method;

FIGS. 2a and 2b are optical micrographs showing surfaces of the nitride single crystals shown in FIGS. 1a and 1b;

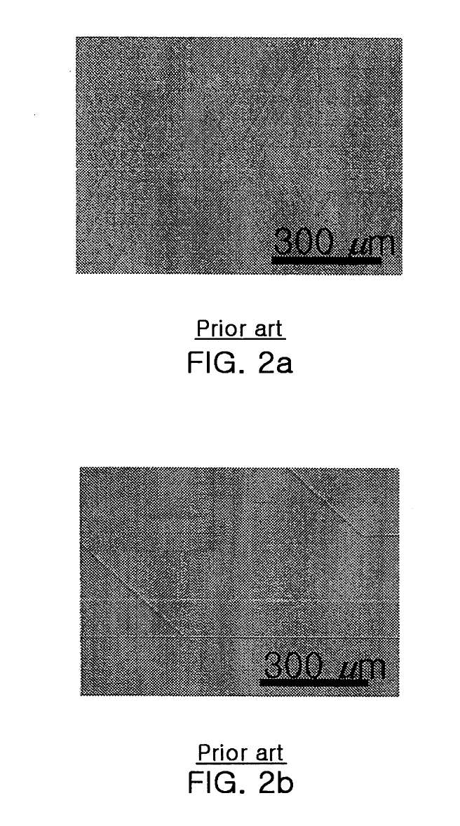

FIGS. 3a and 3b show structures of a nitride single crystal grown on a silicon substrate according to different embodiments of the present invention, respectively; and

FIG. 4 is a section side elevation illustrating a nitride semiconductor light emitting device according to one embodiment of the present invention.

### DESCRIPTION OF THE PREFERRED EMBODIMENTS

Preferred embodiments will now be described in detail with reference to the accompanying drawings.

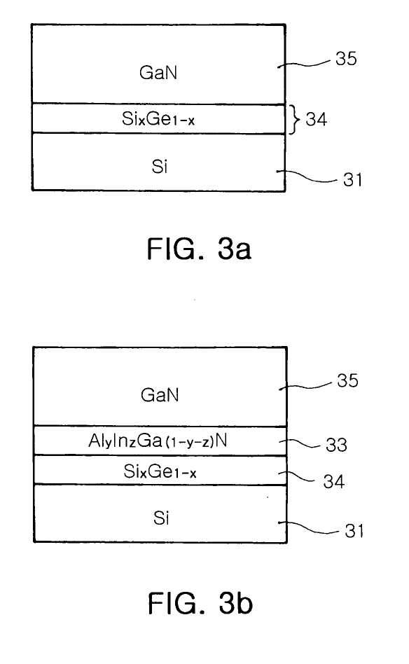

FIGS. 3a and 3b show structures of a GaN single crystal grown by use of a SiGe buffer layer in accordance with the present invention.

According to the embodiment of the present invention shown in FIG. 3a, a SiₓGe₁₋ₓ layer (where 0<x≦1) is provided as a buffer layer 34 on a silicon substrate 31. At this time, the silicon layer 31 has an upper surface of a (111) crystal plane. A GaN single crystal 35 is grown on the SiₓGe₁₋ₓ layer 34 by use of a well-known process of growing a nitride single crystal, such as the MOCVD process. According to the present invention, the SiₓGe₁₋ₓ layer 34 preferably has an Si composition (x) of about 0.1˜0.2, and more preferably of about 0.14. When the SiₓGe₁₋ₓ layer 34 comprises an Si composition (x) of about 0.14, since a difference in thermal expansion coefficient between the GaN layer and the SiₓGe₁₋ₓ layer 34 is approximately 0, stress caused by the difference in thermal expansion coefficient therebetween can be remarkably reduced.

The SiₓGe₁₋ₓ layer 34 may be provided as a structure of a SiGe single layer or of Si/SiGe layers. Preferably, since Si and Ge are perfectly soluble with each other in the SiₓGe₁₋ₓ layer 34, and the Si composition therein can be controlled to be gradually decreased, the SiₓGe₁₋ₓ layer 34 may have an Si composition gradient (x) gradually decreasing from a portion, where the SiₓGe₁₋ₓ layer 34 contacts the silicon substrate 31, to an uppermost portion of the SiₓGe₁₋ₓ layer 34 (that is, to a portion where a GaN single crystal 35 will be formed). The Si composition preferably increase in the range of 1 to 0.1, and more preferably in the range of 1 to 0.14, from the portion where the SiₓGe₁₋ₓ layer 34 contacts the silicon substrate 31 to the uppermost portion of the SiₓGe₁₋ₓ layer 34.

Additionally, unlike the conventional AlN buffer layer, the SiₓGe₁₋ₓ layer 34 may be grown to a thickness, which can sufficiently secure buffering effects between dissimilar materials. For instance, in the case of the conventional AlN buffer layer, it is difficult to grow it to a thickness of 1 μm or more, and thus, there is a problem in that a sufficient buffering region cannot be secured. However, since the SiₓGe₁₋ₓ layer 34 can be grown to a thickness of several dozen nm, it is desirable that the SiₓGe₁₋ₓ layer 34 be grown to a thickness of at least 20 nm in order to secure a sufficient buffering region.

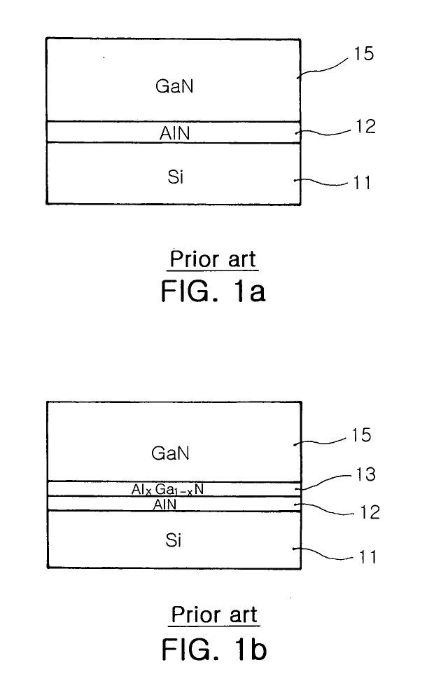

Alternatively, the present invention may be realized as the embodiment shown in FIG. 3b. As with FIG. 3a, according to the embodiment shown in FIG. 3b, after a SiₓGe₁₋ₓ, layer 34 (where 0<x≦1) is formed on a silicon substrate 31, which has an upper surface of a (111) crystal plane, an intermediate layer 33 having the formula of Al_{y}In_{z}Ga_{(1-y-z)}N (where 0≦y≦1, 0≦z≦1, 0≦y+z≦1) may be formed on the SiₓGe₁₋ₓ layer 34. The Al_{y}In_{z}Ga_{(1-y-z)}N intermediate layer 33 acts as a buffer layer, as with the AlGaN layer 13 illustrated in FIG. 1b. According to the embodiment of the present invention, with the stress due to differences in heat expansion coefficient between the layers removed by means of the SiₓGe₁₋ₓ layer 34, growth of a nitride single layer 35 can be imparted with enhanced quality by use of the Al_{y}In_{z}Ga_{(1-y-z)}N intermediate layer 33.

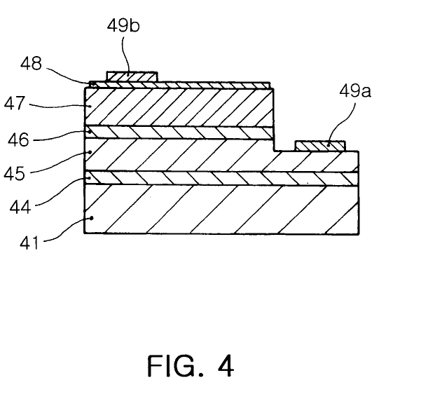

FIG. 4 is a section side elevation illustrating a nitride semiconductor light emitting device according to another embodiment of the present invention.

Referring to FIG. 4, a nitride semiconductor light emitting device 40 according to the present invention comprises a buffer layer 44 having the formula of SiₓGe₁₋ₓ (where 0<x≦1) formed on a silicon substrate 41. The nitride semiconductor light emitting device 40 further comprises a first conductive nitride semiconductor layer 45, an active layer 46, and a second conductive nitride semiconductor layer 47 sequentially formed on the buffer layer 44. Additionally, the nitride semiconductor light emitting device 40 comprises an n-side electrode 49a on an upper surface of the first conductive nitride semiconductor layer 45, where some portion of the second conductive nitride semiconductor layer 47 and active layer 46 is removed, a transparent electrode 48 on the second conductive nitride semiconductor layer 47 for enhancing contact resistance, and a p-side electrode 49b on the transparent electrode 48.

The first conductive nitride semiconductor layer 45 may comprise a first conductive GaN layer formed on the SiₓGe₁₋ₓ buffer layer 44, and a first conductive AlGaN layer on the first conductive GaN layer. The second conductive nitride semiconductor layer 47 may comprise a second conductive GaN layer formed on the active layer 46, and a second conductive AlGaN layer on the second conductive GaN layer. The active layer 46 may be a GaN/InGaN active layer having a multi-well structure.

The SiₓGe₁₋ₓ layer 44 of the present invention preferably has an Si composition (x) of about 0.1˜0.2, and more preferably of about 0.14. When the SiₓGe₁₋ₓ layer 34 has an Si composition (x) of about 0.14, since a difference in thermal expansion coefficient between the GaN layer and the SiₓGe₁₋ₓ layer 34 is approximately 0, stress caused by the differences in thermal expansion coefficient therebetween can be remarkably reduced.

Meanwhile, it should be noted that the present invention is not limited to the above embodiment. For instance, effects of the differences in thermal expansion coefficient between the layers is not restricted to a typical tension, even though the Si composition is reduced below 0.14, the present invention may be designed to intentionally generate a compression stress in order to complement a tension generated in a region between other layers.

Preferably, since Si and Ge are perfectly soluble in the SiₓGe₁₋ₓ layer 44, and the Si composition therein can be controlled to be gradually decreased, the SiₓGe₁₋ₓ layer 44 may have the Si composition gradient (x) gradually decreasing from a portion where the SiₓGe₁₋ₓ layer 44 contacts the silicon substrate 41 to a portion where the SiₓGe₁₋ₓ layer 44 contacts the first conductive nitride semiconductor layer 45. The Si composition preferably increase in the range of 1 to 0.1, and more preferably in the range of 1 to 0.14, from the portion where the SiₓGe₁₋ₓ layer 44 contacts the silicon substrate 41 to the uppermost portion of the SiₓGe₁₋ₓ layer 44. Since the SiₓGe₁₋ₓ layer 34 can be grown to a thickness of several dozen nm, it is desirable that the SiₓGe₁₋ₓ layer 44 be grown to a thickness of at least 20 nm in order to secure a sufficient buffering region.

Furthermore, in the process of manufacturing the nitride semiconductor light emitting device, since the SiₓGe₁₋ₓ buffer layer can be easily etched, it is advantageous in that the Si substrate can be lifted off, if necessary.

Meanwhile, although the structure shown in FIG. 4 has only the SiGe buffer layer, as with the embodiment shown in FIG. 3b, after the SiₓGe₁₋ₓ layer 44 (where 0<x≦1) is formed on the silicon substrate 41, which has an upper surface of a (111) crystal plane, an intermediate layer having the formula of Al_{y}In_{z}Ga_{(1-y-z)}N (where 0≦y≦1, 0≦z≦1, 0≦y+z≦1) may be formed on the SiₓGe₁₋ₓ layer 44.

As apparent from the above description, according to the present invention, the method of growing a high quality nitride single crystal by use of the buffer layer comprising Si and Ge on the silicon substrate. The buffer layer of the present invention has a thermal expansion coefficient approximately similar to that of the GaN single crystal, sufficiently secures a growth thickness, and makes it possible to generate an intentional compression stress for compensating for a tension generated from other regions, enabling a high quality nitride single crystal to be grown on the silicon substrate.

Accordingly, in manufacturing the nitride semiconductor light emitting device, the silicon substrate may be used as a substrate for growth of the nitride single crystal, instead of a sapphire substrate or a SiC substrate having a high price.

It should be understood that the embodiments and the accompanying drawings as described above have been described for illustrative purposes and the present invention is limited by the following claims. Further, those skilled in the art will appreciate that various modifications, additions and substitutions are allowed without departing from the scope and spirit of the invention as set forth in the accompanying claims.

1. A method of growing a nitride single crystal layer, comprising the steps of:
preparing a silicon substrate having an upper surface of a crystal plane (111);
forming a buffer layer having the formula of SiₓGe₁₋ₓ, (where 0<x≦1) on the upper surface of the silicon substrate; and
forming a nitride single crystal on the buffer layer.

2. The method as set forth in claim 1, further comprising:
forming an intermediate layer having the formula of Al_{y}In_{z}Ga_{(1-y-z)}N, (where 0≦y≦1, 0≦z≦1, 0≦y+z≦1) on the buffer layer before forming the nitride single crystal.

3. The method as set forth in claim 1, wherein the buffer layer has an Si composition (x) of about 0.1˜0.2.

4. The method as set forth in claim 1, wherein the buffer layer has an Si composition gradient (x) gradually decreasing from a portion, where the buffer layer contacts the silicon substrate, to an uppermost portion of the buffer layer.

5. The method as set forth in claim 4, wherein the buffer layer has an Si composition gradient (x) gradually decreasing from 1 to 0.1 from the portion, where the buffer layer contacts the silicon substrate, to the uppermost portion of the buffer layer, respectively.

6. The method as set forth in claim 4, wherein the buffer layer has an Si composition gradient (x) gradually decreasing from 1 to 0.14 from the portion, where the buffer layer contacts the silicon substrate, to the uppermost portion of the buffer layer, respectively.

7. The method as set forth in claim 1, wherein the buffer layer has a thickness of at least 20 nm.

8. A nitride semiconductor light emitting device comprising:
a silicon substrate having an upper surface of a (111) crystal plane;
a buffer layer having the formula of SiₓGe₁₋ₓ, (where 0<x≦1) on the upper surface of the silicon substrate;
a first conductive nitride semiconductor layer on the buffer layer;
an active layer on the first conductive nitride semiconductor layer; and
a second conductive nitride semiconductor layer on the first conductive nitride semiconductor layer.

9. The device as set forth in claim 8, further comprising:
an intermediate layer having the formula of Al_{y}In_{z}Ga_{(1-y-z)} N, (where 0≦y≦1, 0≦z≦1, 0≦y+z≦1) on the buffer layer.

10. The device as set forth in claim 8, wherein the buffer layer has an Si composition (x) of about 0.1˜0.2.

11. The device as set forth in claim 8, wherein the buffer layer has an Si composition gradient (x) gradually decreasing from a portion, where the buffer layer contacts the silicon substrate, to an uppermost portion of the buffer layer.

12. The device as set forth in claim 11, wherein the buffer layer has an Si composition gradient (x) gradually decreasing from 1 to 0.1 from the portion, where the buffer layer contacts the silicon substrate, to the uppermost portion of the buffer layer, respectively.

13. The device as set forth in claim 11, wherein the buffer layer has an Si composition gradient (x) gradually decreasing from 1 to 0.14 from the portion, where the buffer layer contacts the silicon substrate, to the uppermost portion of the buffer layer, respectively.

14. The device as set forth in claim 8, wherein the buffer layer has a thickness of at least 20 nm.

15. A method of manufacturing a nitride semiconductor light emitting device, comprising the steps of:
preparing a silicon substrate having an upper surface of a (111) crystal plane;
forming a buffer layer having the formula of SiₓGe₁₋ₓ, (where 0<x≦1) on the upper surface of the silicon substrate;
forming a first conductive nitride semiconductor layer on the buffer layer;
forming an active layer on the first conductive nitride semiconductor layer; and
forming a second conductive nitride semiconductor layer on the first conductive nitride semiconductor layer.

16. The method as set forth in claim 15, further comprising:
forming an intermediate layer having the formula of Al_{y}In_{z}Ga_{(1-y-z)}N, (where 0≦y≦1, 0≦z≦1, 0≦y+z≦1) on the buffer layer before forming the first nitride semiconductor layer.

17. The method as set forth in claim 15, wherein the buffer layer has an Si composition (x) of about 0.1˜0.2.

18. The method as set forth in claim 15, wherein the buffer layer has an Si composition gradient (x) gradually decreasing from a portion, where the buffer layer contacts the silicon substrate, to an uppermost portion of the buffer layer.

19. The method as set forth in claim 18, wherein the buffer layer has an Si composition gradient (x) gradually decreasing from 1 to 0.1 from the portion, where the buffer layer contacts the silicon substrate, to the uppermost portion of the buffer layer, respectively.

20. The method as set forth in claim 18, wherein the buffer layer has an Si composition gradient (x) gradually decreasing from 1 to 0.14 from the portion, where the buffer layer contacts the silicon substrate, to the uppermost portion of the buffer layer, respectively.

21. The method as set forth in claim 15, wherein the buffer layer has a thickness of at least 20 nm.
